(19) United States
(12) Patent Application Publication
(10) Pub. No.: US 2008/0085013 A1
(43) Pub. Date: Apr. 10, 2008

(54) Feedback cancellation in a sound system

(75) Inventor: Deepak Somasundaram, Petaluma, CA (US)

Correspondence Address: BIRCH STEWART KOLASCH & BIRCH, PO BOX 747, FALLS CHURCH, VA, 22040-0747, US

(73) Assignee: PHONIC EAR INC., Petaluma, CA (US)

(21) Appl. No.: 11/544,919

(22) Filed: Oct. 10, 2006

Related U.S. Application Data
(60) Provisional application No. 60/846,097, filed on Sep. 21, 2006.

(51) Int. Cl. H04R 3/00; H03G 5/00; H03G 9/00

(52) U.S. Cl. 381/95; 381/98; 381/102

(57) ABSTRACT

This invention relates to a sound system and method for processing acoustical sound. The sound system comprises a microphone for converting an acoustical sound to an electrical sound signal, a processor for processing the sound signal and for generating a processed sound signal, and a speaker for converting the processed sound signal to a processed acoustical sound. The processor comprises a calculating unit for calculating a threshold value based on mean magnitude and standard deviation of the sound signal, a FFT unit for transforming the sound signal into frequency domain, a peak identification unit for identifying a peak in the sound signal in frequency domain and for generating a peak signal, a comparator for comparing the threshold value with the peak signal and for generating a control signal identifying frequency of said peak, and a programmable notch-filter unit receiving said control signal and filtering out a bandwidth of the sound signal in accordance with the control signal thereby generating the processed sound signal.

### FIELD OF INVENTION

This invention relates to a method and system for cancellation of acoustical feedback in a sound system, such as a public address sound system or a classroom sound system i.e. assistive learning system.

### BACKGROUND OF INVENTION

American patent no.: U.S. Pat. No. 5,245,665 discloses a method and apparatus for eliminating acoustical feedback in a sound amplification system, wherein a sound is converted into a digital signal to be converted to a frequency spectrum by a Fast Fourier Transform (FFT) in a computer. Successive frequency spectrums are examined by the computer to determine the presence of an acoustic resonating feedback signal, and one or more filter devices are controlled by the computer for attenuating one or more narrow frequency bands of the amplified sound to eliminate undesirable acoustic feedback. The computer determines a maximum magnitude frequency which is then compared with the magnitude of one or more harmonics and/or sub-harmonics of the maximum magnitude frequency so as to establish whether the maximum magnitude frequency is greater by a predetermined factor, which would indicate a candidate resonating feedback frequency. The presence of a candidate resonating feedback frequency in a plurality of a predetermined number of successive frequency spectrums indicate the candidate resonant frequency is a resonating feedback frequency to be attenuated. The computer subsequently establishes programmable notch-filters to suppress the resonating feedback frequency.

M. H. Er et al, further, in Microprocessors and Microsystems Volume 18 no. 1 January/February 1994, in an article entitled “A DSP-based acoustic feedback canceller for public address systems”, discloses design and implementation of a DSP-based acoustic feedback canceller system using the TMS320C25 chip. The disclosed system consists of a stand-alone unit with DSP hardware and built-in firmware. An algorithm employs the use of a FFT for converting time varying signals into frequency spectrums, which are scanned for potential resonating feedback signals. Once identified, a second order Infinite Impulse Response (IIR) notch-filter is used for cancelling the identified resonating frequency signal.

The above referred prior art documents although providing a reduction of the effects of positive feedback require a great number of computations and therefore require a lot of processing power.

### SUMMARY OF THE INVENTION

An object of the present invention is to provide a sound system having a simple and effective means for eliminating acoustical feedback, and which requires only a few processing steps.

A particular advantage of the present invention is the provision of one or more notch-filters engaging in the signal path softly thus avoiding unnecessary processing artefacts.

A particular feature of the present invention is utilisation of an understanding of the statistical distribution of a speech signal in the frequency domain.

The above object, advantage and feature together with numerous other objects, advantages and features, which will become evident from below detailed description, are obtained according to a first aspect of the present invention by a sound system for processing acoustical sound and comprising a microphone adapted to convert an acoustical sound to an electrical sound signal, a processor adapted to process said sound signal and to generate a processed sound signal, and a speaker adapted to convert said processed sound signal to a processed acoustical sound, and wherein said processor comprising a calculating unit adapted to calculate a threshold value based on mean magnitude and standard deviation of said sound signal, a FFT unit adapted to transform said sound signal into frequency domain, a peak identification unit adapted to identify a peak in said sound signal in frequency domain and to generate a peak signal, a comparator adapted to compare said threshold value with said peak signal and to generate a control signal identifying frequency of said peak, and a programmable notch-filter unit adapted to receive said control signal and operable to filter out a bandwidth of said sound signal in accordance with said control signal thereby generating said processed sound signal.

The sound system according to the first aspect of the present invention thus may advantageously utilise the fact that vocal sound has a Gaussian distribution in the time domain and the fact that most energy is of the vocal sound is within one standard deviation from the centre frequency. Hence the sound system may be particularly useful in situations where vocal sound is to be amplified.

The term “a” is in this context to be construed as one or more, a plurality, or a multiplicity of elements.

Further, the term “processor” is in this context to be construed as a unit capable of performing a wide range of mathematical processes such as achieved by a microprocessor, a microcontroller, a central processing unit, and/or a digital signal processor. Hence the processor is capable of implementing a transfer function for a sound signal, i.e. providing a required gain in accordance with frequency.

The programmable notch-filter according to the first aspect may comprise a leaky integrator operable to control attack time of said programmable notch-filter. The leaky integrator ensures that the notch-filter gradually reduces the sound signal in the frequency domain in a bandwidth of the notch-filter so that artefacts introduced by steep edged notch-filters are avoided. The leaky integrator is computationally efficient for the sound system since it requires only three mathematical operations.

Further, the leaky integrator may be operable to control the attack times of the programmable notch-filter in accordance with frequency. That is, the leaky integrator may be adapted to be operable having a first attack time for a first frequency bandwidth and having a second attack time for a second frequency bandwidth. Thus the leaky integrator may be operable having a long attack time in the high frequency part of said sound signal in said frequency domain and having a short attack time in the low frequency part of said sound signal in said frequency domain.

The term “attack time” is in this context to be construed as the time it takes for the programmable notch-filter from receiving a control signal to fully engaging the filter. Further, “attack time” is in this context to be construed as similar to “release time” being the opposite, namely the time it takes for the programmable notch-filter from receiving a control signal to fully disengaging the filter.

The processor according to the first aspect of the present invention may further comprise a counter unit adapted to count a number of frequencies of said sound signal in the frequency domain having magnitudes above said threshold value. The counter unit may be adapted to provide a gain control signal to said processor when the count of said frequencies is above a predetermined number. Hence, the processor when receiving the gain control signal may reduce gain throughout the frequency spectrum. This is, particularly, advantageous since by identifying a plurality of frequencies in the sound signal in the frequency domain may demonstrate an acoustical feedback is present. For example, the predetermined number may be in the range between 2 to 10 such as 3.

The programmable notch-filter according to the first aspect of the present invention may be operable to establish a number of parallel notch-filters each having a selected operating bandwidth obviously, any number of parallel notch-filters may be established each having a selected operating bandwidth and centre frequency; however, the number may be limited to the predetermined number defined above.

The programmable notch-filter according to the first aspect of the present invention may be operable to receive the sound signal in the time domain or to receive the sound signal in the frequency domain. The configuration of the programmable notch-filter is thus not limiting to the sound system.

In addition, the programmable notch-filter according to the first aspect of the present invention may comprise amplifying means adapted to amplify the sound signal in accordance with a predetermined transfer function. The programmable notch-filter may be implemented as an active filter such as an infinite impulse response filter.

The above objects, advantages and features together with numerous other objects, advantages and features, which will become evident from below detailed description, are obtained according to a second aspect of the present invention by a method for processing acoustical sound and comprising:

(a) converting an acoustical sound to a sound signal,

(b) calculating a threshold value based on mean magnitude and standard deviation of said sound signal,

(c) transforming said sound signal into frequency domain,

(d) identifying a peak in said sound signal in frequency domain and generating a peak signal,

(e) comparing said threshold value with said peak signal and generating a control signal identifying frequency of said peak when said peak signal is above said threshold value,

(f) filtering out a bandwidth of said sound signal according to said control signal thereby generating a filtered sound signal,

(g) processing said filtered sound signal and generating a processed sound signal,

(h) converting said processed sound signal to a processed acoustical sound.

The method according to the second aspect of the present invention may comprise any elements of the sound system according to the firs aspect of the present invention.

### BRIEF DESCRIPTION OF THE DRAWINGS

The above, as well as additional objects, features and advantages of the present invention, will be better understood through the following illustrative and non-limiting detailed description of preferred embodiments of the present invention, with reference to the appended drawing, wherein:

FIG. 1, shows a block diagram of a sound system according to a first embodiment of the present invention;

FIG. 2, shows a block diagram of a sound processor for the sound system according to a first and presently preferred embodiment of the present invention;

FIG. 3, shows a further block diagram of a sound processor for the sound system according to a second embodiment of the present invention;

FIG. 4, shows a further block diagram of a sound processor for the sound system according to a third embodiment of the present invention; and

FIG. 5, shows a further block diagram of a sound processor for the sound system according to a fourth embodiment of the present invention.

### DETAILED DESCRIPTION OF PREFERRED EMBODIMENTS

In the following description of the various embodiments, reference is made to the accompanying figures, which show by way of illustration how the invention may be practiced. It is to be understood that other embodiments may be utilized and structural and functional modifications may be made without departing from the scope of the present invention.

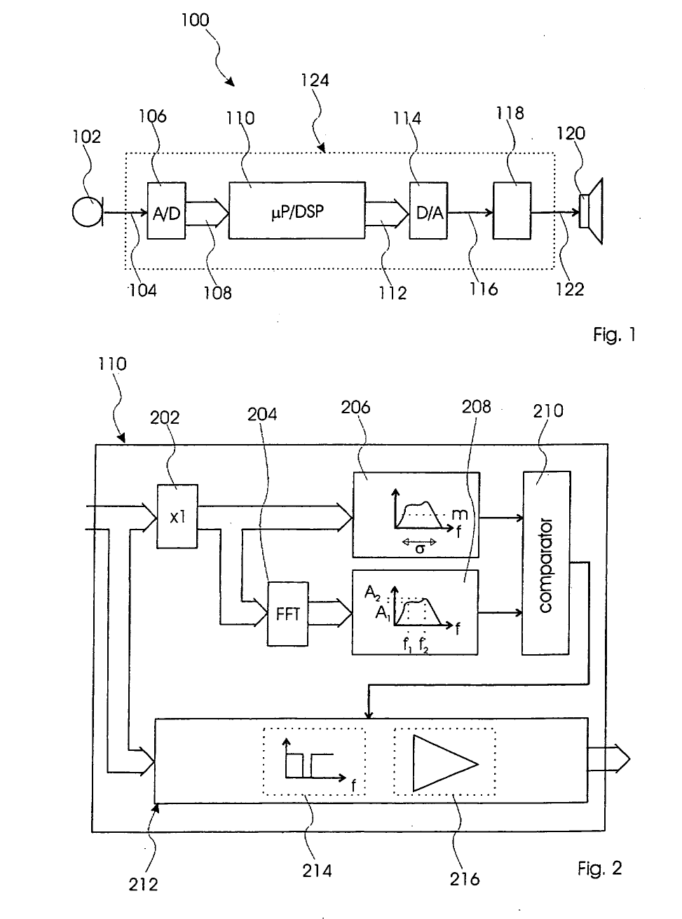

FIG. 1, shows a block diagram of a sound system according to the first embodiment of the present invention and designated in entirety by reference numeral 100. The sound system 100 comprises a microphone unit 102 converting a sound to an analogue electrical sound signal. The analogue electrical sound signal is communicated through a first communication path 104 to an analogue-to-digital (A/D) converter 106, which converts the analogue electrical sound signal into a digital sound signal. The digital sound signal is communicated through a second communication path 108 to a sound processor 110, which processes the digital signal in accordance with a predetermined transfer function. The second communication path 108 may be a multi-channel bus. The sound processor 110 generates a processed digital signal and communicates this through a third communication path 112 to a digital-to-analogue (D/A) converter 114. The third communication path 112 may be identical to the second communication path 108 i.e. a controlled multi-channel bus. The D/A converter 114 converts the processed digital signal into a processed analogue signal and communicates this through a fourth communication path 116 to a driver 118. Finally, the driver 118 is connected to a loud speaker 120 through a fifth communication path 122 and is adapted to drive the loud speaker 112 to present a processed sound

A large part of the sound system 100 may in fact be implemented as integrated elements so that the sound system 100 comprises the microphone unit 102, the speaker unit 120 and a digital signal processor 124.

The sound processor 110 as shown in FIG. 2 comprises an input buffer unit 202 adapted to buffer the digital signals into a number (N) of frames, which are communicated to a FFT unit 204 transforming the frames into frequency domain signals and to a S threshold calculation unit 206 adapted to calculate a threshold value from the frame based on mean magnitude (m) and standard deviation (σ) of the frames. For example the threshold value may be determined in accordance with formula 1 below.

Threshold_value=m+α·σ (Formula 1),

where “m” is the mean magnitude of the frame, “α” is a multiplication factor and “σ” is standard deviation of the frame. The calculation of the threshold value may further be adjusted by a bias. The multiplication factor “α” may have any real number; however the presently preferred number is 2, since this provides for most of the energy of the frame if the frame contain vocal information.

The transformed frame is forwarded from the FFT unit 204 to a peak identification unit 208 adapted to identify peaks in the transformed frame and to generate a peak signal for each peak identified in the transformed frame. The peak signal provides information of magnitude and frequency of the peak. The peak identification unit 208 may be configured to identify any number of peaks such as in the range one to ten, for example identifying the three largest peaks in each transformed frame. The peak identification unit 208 may comprise a counter for counting number of peaks and may be adapted to generate a flag signal when the number of peaks identified equals a pre-selected number.

The threshold calculation unit 206 generates a threshold signal for each frame and forwards the threshold signal to a comparator unit 210, which compares the threshold signal to the peak signals received from the peak identification unit 208.

The calculation of the mean magnitude of the frequency spectrum in a frame may advantageously be established by a squared addition of the real and imaginary parts of the digital signals. Further, the calculation of the mean magnitude of the digital signals may advantageously be established by a vector magnitude computation such as suggested by Richard G. Lyons in “Understanding Digital Signal Processing” 2nd edition (the αMax+βMin method). It should be understood that any calculation or estimation know to a person skilled in the art may be employed.

The comparator unit 210 generates a filter control signal in case the peak signal is greater than the threshold value, which filter control signal is forwarded to a filter/amplifier unit 212. The filter/amplifier unit 212 comprises a programmable notch-filter 214 and an amplifier 216, and is adapted to receive the digital sound signal and filter the digital sound signal according to the filter control signal by means of the programmable notch-filter 214, and to amplify the potentially filtered digital sound signal according to a predetermined transfer function by means of the amplifier 216. In this context the term “amplify” is to be construed as increasing or decreasing any particular frequency regions.

The filter/amplifier unit 212 may be implemented as an active filter such as an infinite impulse response (IIR) filter.

The programmable notch-filter 214 may comprise a leaky integrator adapted to provide a gradual engagement of the notch-filter 214 so as to avoid artefacts caused by the notch-filter's 214 sharp edges to be generated. For example, the leaky integrator may be operable so that the effect of the notch-filter is engaged and disengaged slowly. The leaky integrator may be implemented by any means know to a person skilled in the art.

In case the peak identification unit 208 identifies a maximum number of peaks within a frame the comparator 210 generates an alert signal, which causes the filter/amplifier unit 212 to reduce gain of the amplifier 216. The effect of the reduction of the gain is monitored on the following frames. That is, if the peak identification unit 208 fails to identify new peaks in the next frames then the gain is gradually increased.

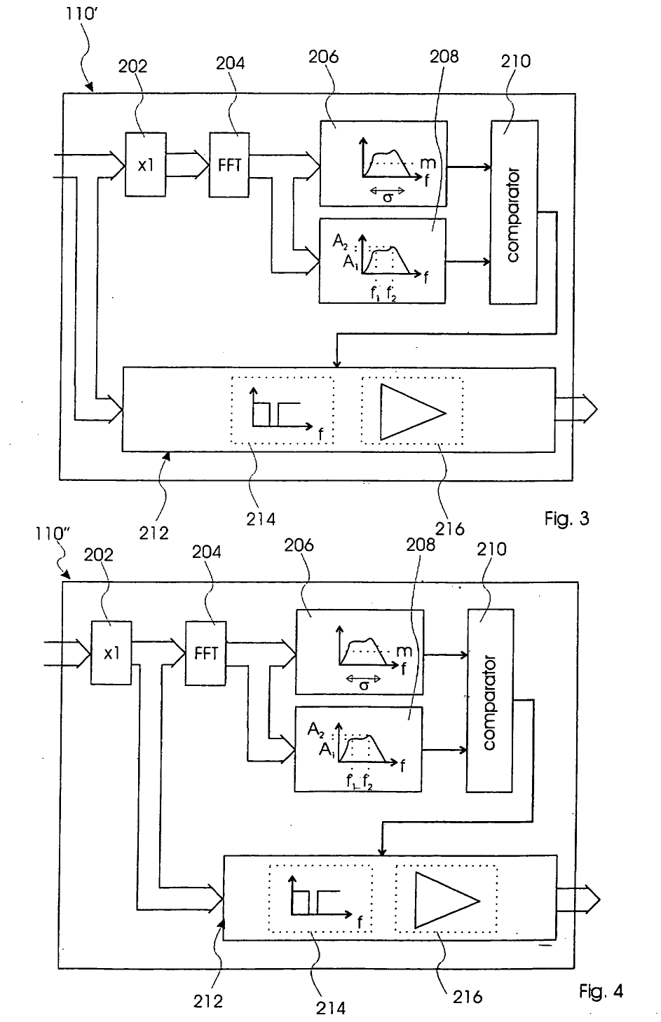

FIG. 3, shows a block diagram of a sound processor 110′ according to a second embodiment of the present invention, which comprises the same elements of the sound processor 110 and these are referenced by the same numerals. The sound processor 110′ differs from the sound processor 110 by having the FFT unit 204 transforming the frames into frequency domain signals, which are then communicated to the threshold calculation unit 206 in this case being adapted to calculate a threshold value from the frame based on mean magnitude and standard deviation of the frequency spectrum of the frame.

FIG. 3, shows a block diagram of a sound processor 110″ according to a second embodiment of the present invention. The sound processor 110′ comprises the same elements of the sound processor 110 and 110′ and these are referenced by the same numerals. The sound processor 110″, however, differs from the sound processor 110′ by having the filter/amplifier unit 212 receive frames from the buffer unit 202 and thus perform filtering and amplifying operations on the frames rather than directly on the digital sound signal.

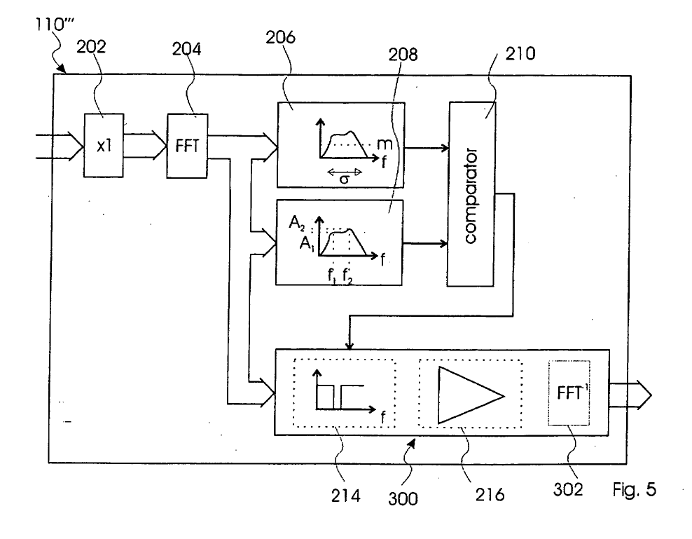

FIG. 4, shows a further block diagram of a sound processor 110′″ according to a third embodiment of the present invention. The sound processor 110′″ comprises the same elements of the sound processors 110, 110′ and 110″ and these are referenced by the same numerals. The sound processor 110″, however, differs from the sound processors 110 and 110′ by having a filter/amplification unit 300 receiving the sound signal in the frequency domain from the FFT unit 204 and thus performing the filtering and amplifying operations on the sound signal in the frequency domain rather than on the digital sound signal or on the frames. The filter/amplification unit 300 further comprises an inverse FFT unit 302 for inverting the processed sound signal in the frequency domain back into a processed sound signal in the time domain.

1. A sound system for processing acoustical sound and comprising a microphone adapted to convert an acoustical sound to a sound signal, a processor adapted to process said sound signal and to generate a processed sound signal, and a speaker adapted to convert said processed sound signal to a processed acoustical sound, and wherein said processor comprising a calculating unit adapted to calculate a threshold value based on mean magnitude and standard deviation of said sound signal, a FFT unit adapted to transform said sound signal into -frequency domain, a peak identification unit adapted to identify a peak in said sound signal in frequency domain and to generate a peak signal, a comparator adapted to compare said threshold value with said peak signal and to generate a control signal identifying frequency of said peak, and a programmable notch-filter unit adapted to receive said control signal and operable to filter out a bandwidth of said sound signal in accordance with said control signal thereby generating said processed sound signal.

2. A sound system according to claim 1, wherein said programmable notch-filter comprises a leaky integrator operable to control attack time of said programmable notch-filter.

3. A sound system according to claim 2, wherein said leaky integrator is operable to control the attack times of the programmable notch-filter in accordance with frequency.

4. A sound system according to claim 3, wherein said leaky integrator is operable to having a first attack time for a first frequency bandwidth and having a second attack time for a second frequency bandwidth.

5. A sound system according to claim 4, wherein said leaky integrator is operable to having a long attack time in the high frequency part of said sound signal in said frequency domain and having a short attack time in the low frequency part of said sound signal in said frequency domain.

6. A sound system according to any of claims 1 to 5, wherein said processor further comprises a counter unit adapted to count a number of frequencies of said sound signal in the frequency domain having magnitudes above said threshold value.

7. A sound system according to claim 6, wherein said counter unit is adapted to providing a gain control signal to said processor when the count of said frequencies is above a predetermined number.

8. A sound system according to claim 1, wherein said programmable notch-filter is operable to establishing a number of parallel notch-filters each having a selected operating bandwidth.

9. A sound system according to claim 1, wherein said programmable notch-filter is operable to receive said sound signal in the time domain.

10. A sound system according to claim 1, wherein said programmable notch-filter is operable to receive said sound signal in the frequency domain.

11. A sound system according to claim 1, wherein said programmable notch-filter comprises amplifying means adapted to amplify said sound signal in accordance with a predetermined transfer function.

12. A sound system according to claim 1, wherein said programmable notch-filter comprises an infinite impulse response filter.

13. A method for processing acoustical sound and comprising:
(a) converting an acoustical sound to a sound signal,
(b) calculating a threshold value based on mean magnitude and standard deviation of said sound signal,
(c) transforming said sound signal into frequency domain,
(d) identifying a peak in said sound signal in frequency domain and generating a peak signal,
(e) comparing said threshold value with said peak signal and generating a control signal identifying frequency of said peak when said peak signal is above said threshold value,
(f) filtering out a bandwidth of said sound signal according to said control signal thereby generating a filtered sound signal,
(g) processing said filtered sound signal and generating a processed sound signal,
(h) converting said processed sound signal to a processed acoustical sound.
